(19) United States
(12) Patent Application Publication
(10) Pub. No.: US 2025/0314697 A1
(43) Pub. Date: Oct. 9, 2025

(54) METHODS AND APPARATUSES FOR A MATRIX SCAN ARCHITECTURE

(71) Applicant: Analog Devices International Unlimited Company, Limerick (IE)

(72) Inventors: Hector BARRERAS ALMARCHA, Valencia (ES); Guillermo Oliver, Valencia (ES); Daniel Jimenez, Alboraya (ES); Issac Molina, Valencia (ES)

(21) Appl. No.: 19/170,713

(22) Filed: Apr. 4, 2025

Related U.S. Application Data
(60) Provisional application No. 63/631,342, filed on Apr. 8, 2024.

(51) Int. Cl. G01R 31/3185

(52) U.S. Cl. CPC G01R 31/318552; G01R 31/318575

(57) ABSTRACT

Aspects of the present disclosure include a matrix circuit having a clock circuit configured to output a first group of output clock signals and one or more additional groups of output clock signals, the clock circuit including at least one clock staggering circuit configured to delay remaining output clock signals of the first group of output clock signals or the one or more additional groups of output clock signals with respect to a corresponding initial output clock signal of the first group of output clock signals or the one or more additional groups of output clock signals, and at least one clock sequencing circuit configured to output, after one or more time intervals, each of the one or more additional groups of output clock signals with respect to the first group of output clock signals.

### CROSS-REFERENCE TO RELATED APPLICATIONS

The present application claims priority to, and the benefit of, U.S. Provisional Application No. 63/631,342 filed Apr. 8, 2024, the entire contents of which are hereby incorporated by reference herein.

### BACKGROUND

Many devices may be tested and/or measured prior to deployment to ensure proper functions. During the testing/measurement process, it may be desirable to decrease the time for the testing process to improve the overall throughput of the number of devices being tested. However, this may be difficult to achieve for certain devices due to power constraints because of the limited amount of power the devices are able to receive during the testing process. This limited amount of power over a limited testing time generally cannot be increased, hence, the testing process duration must be extended, which may negatively impact productivity. Therefore, improvements are desirable.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

Aspects of the present disclosure include a matrix circuit having a clock circuit configured to output a first group of output clock signals and one or more additional groups of output clock signals, the clock circuit comprising: at least one clock staggering circuit configured to delay remaining output clock signals of the first group of output clock signals or the one or more additional groups of output clock signals with respect to a corresponding initial output clock signal of the first group of output clock signals or the one or more additional groups of output clock signals, and at least one clock sequencing circuit configured to output, after one or more time intervals, each of the one or more additional groups of output clock signals with respect to the first group of output clock signals, and a plurality of groups of partitions, each partition being configured to receive a different output clock signal from the first group of output clock signals or the one or more additional groups of output clock signals.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is a schematic diagram of an example of a clock staggering circuit and a graph of an input signal and corresponding staggered output signals over time, according to some aspects of the present disclosure.

FIG. 2 is a schematic diagram of an example of a staggered clock circuit according to some aspects of the present disclosure.

FIG. 3 is a schematic diagram of an example of a clock sequencing circuit and a graph of an input signal and corresponding sequenced output signals over time, according to some aspects of the present disclosure.

FIG. 4 is a schematic diagram of an example of a sequenced clock circuit according to some aspects of the present disclosure.

FIG. 5 is a schematic diagram of an example a matrix scan circuit according to some aspects of the present disclosure.

FIG. 6 is a block diagram of an example of a measurement system according to some aspects of the present disclosure.

FIG. 7 is a flowchart of an example of a method of performing a matrix scan according to some aspects of the present disclosure

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Aspects of the present disclosure include schemes to reduce power consumption surge in a test of integrated circuit (IC) operation, such as during scan shift of a scan test, that requires a significant amount of current through the IC. In designs with power network constraints, a single shift cycle may result in a current surge that may cause an unacceptable voltage (i.e., IR) drop requirement, leading to a false failure on the tester and reducing yield. To address this problem and other shortcomings of prior solutions, a flexible, efficient matrix-like architecture that spreads the current demand over the scan cycle without sacrificing scan throughput is presented. This architecture may be adopted to abide by the power constraints and tester time requirements.

Devices with sufficient pin counts may use multiple input pins as separate scan clocks to be externally staggered. This solution, however, may not be applicable to devices with restrictive pin counts that need to maximize the number of pins used as scan chain input and outputs instead of power deliveries and/or clock triggers.

Aspects of the present disclosure include a matrix-like scan design for test (DFT) architecture that spreads the current demand surges. As such, surges of power consumption from various portions of the IC may be spread over the full scan cycle without sacrificing throughput or test coverage, and without increasing the number of device pins required for the scan solution.

In some aspects, a matrix architecture of the current disclosure may include embedded clock staggering and clock sequencing to create a 2-D array of scan shift clocks internal to the design that will pulse in succession during each scan cycle. The design sequential elements (e.g., flip-flops or latches) are then divided in different groups, each of which receives one of these scan shift clocks, spreading the current demand from both the clock tree and the sequential elements groups over the cycle.

Since the number of pins available to be used as scan inputs and outputs is limited, scan shift transfers between the different groups of sequential elements often become inevitable, and to avoid timing-related issues and to optimize overall throughput, aspects of the present disclosure include triggering in succession various portions of the matrix to avoid false negative results.

Some aspects of the present disclosure include compaction-based designs, where the same architecture may operate in full scan mode by wrapping around an end of a scan channel with a beginning of a next scan channel via some circuit that guarantees a proper transfer between the intervening endpoints.

In certain aspects, a tester may change the scan inputs and probe the scan outputs once for every sequenced clock in each scan cycle, increasing the controllability and observability of the scan solution. This may be achieved by the replication of the input pipes (as many times as there are sequenced clocks), and/or the addition of multiplexers (MUXs) at the inputs of the output pipes (to mux between as many inputs as there are sequenced clocks).

In an aspect of the present disclosure, a scan shift involves the transmission of a pseudorandom binary stream across design sequential elements to enable the stimulus of certain failure mechanisms during the IC test. During a scan shift cycle, current is drawn by clock tree cells, sequential and/or combinational elements, and/or waste sinks. Synchronous in nature and with usually small clock tree skews, a scan shift cycle may result in a higher peak current demand than functional operation modes since a significant amount of sequential elements may change state every scan cycle.

If a power grid is not be able to provide sufficient power during these current surges, dynamic voltage drop (V=IR) drop may occur. These voltage drops may lead to false tester failures on properly manufactured devices.

In an aspect of the current disclosure, since the current demand originates in the propagation of the scan clock, spacing the clock edges over the scan cycle effectively spreads this current demand.

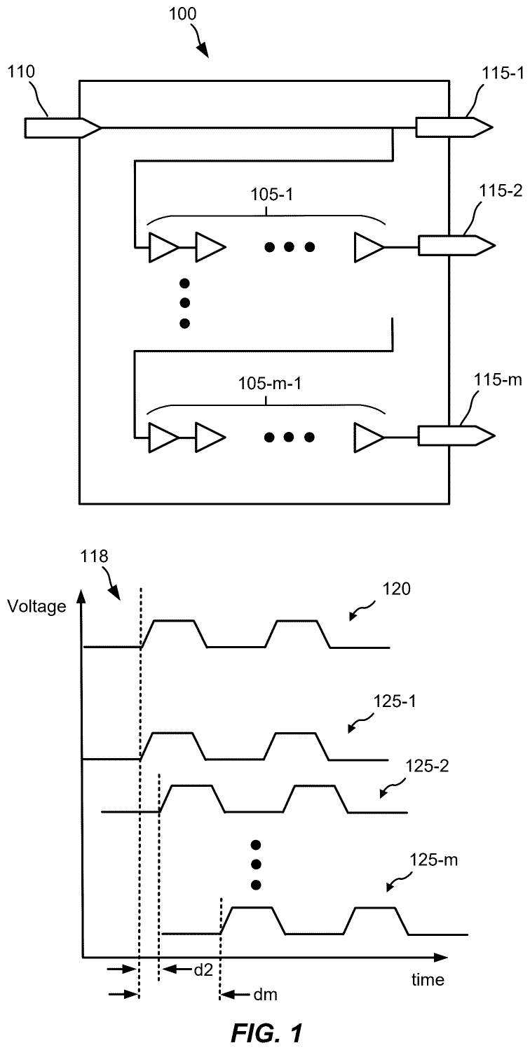

FIG. 1 illustrates an example of a clock staggering circuit scheme, including a clock staggering circuit 100 and a graph of an input signal and corresponding staggered output signals scheme 118, over time, according to aspects of the present disclosure. In an aspect, the clock staggering circuit 100 may include an input terminal 110 and a plurality of output terminals 115-1, 115-2 . . . 115-m, where m is positive integer. The clock staggering circuit 100 may include one or more plurality of delay lines 105-1 . . . 105-(m−1) configured to introduce delays in one or more of a plurality output clock signals 125-1, 125-2 . . . 125-m as described below.

In some aspects of the present disclosure, and additionally referring to graph of an input signal—staggered output signals scheme 118, the clock staggering circuit 100 may receive an input clock signal 120 at the input terminal 110. The first output terminal 115-1 may output a first output clock signal 125-1. Here, there may be no delay between the input clock signal 120 and the first output clock signal 125-1. Inside the clock staggering circuit 100, the input clock signal 120 may be additionally provided as an input to a first plurality of delay lines 105-1. The first plurality of delay lines 105-1 may introduce a delay to the input clock signal 120 and output a second output clock signal 125-2, which adds a delay, d2, relative to the input clock signal 120, at the second output terminal 115-2.

In some aspects of the present disclosure, the second output clock signal 125-2 may be additionally provided as an input to a next plurality of delay lines (e.g., a second plurality of delay lines) to introduce a further delay to the second output clock signal 125-2, and so on, up to a delay, dm, for an m^{th} output signal. The process above may be repeated any number of times to introduce various delays to the input clock signal 120. Each of the plurality of delay lines 105-1, . . . 105-(m−1) may introduce the same or different amount of delays according to various aspects of the present disclosure.

In some aspects of the present disclosure, the plurality output clock signals 125-1, 125-2 . . . 125-m may be separated by a same delay duration or different delay durations. In one example aspect, a maximum delay of the plurality output clock signals 125-1, 125-2 . . . 125-m may be less than or equal to a period of the input clock signal 120. In another example, a maximum delay of the plurality of output clock signals 125-1, 125-2 . . . 125-m may be greater than a period of the input clock signal 120.

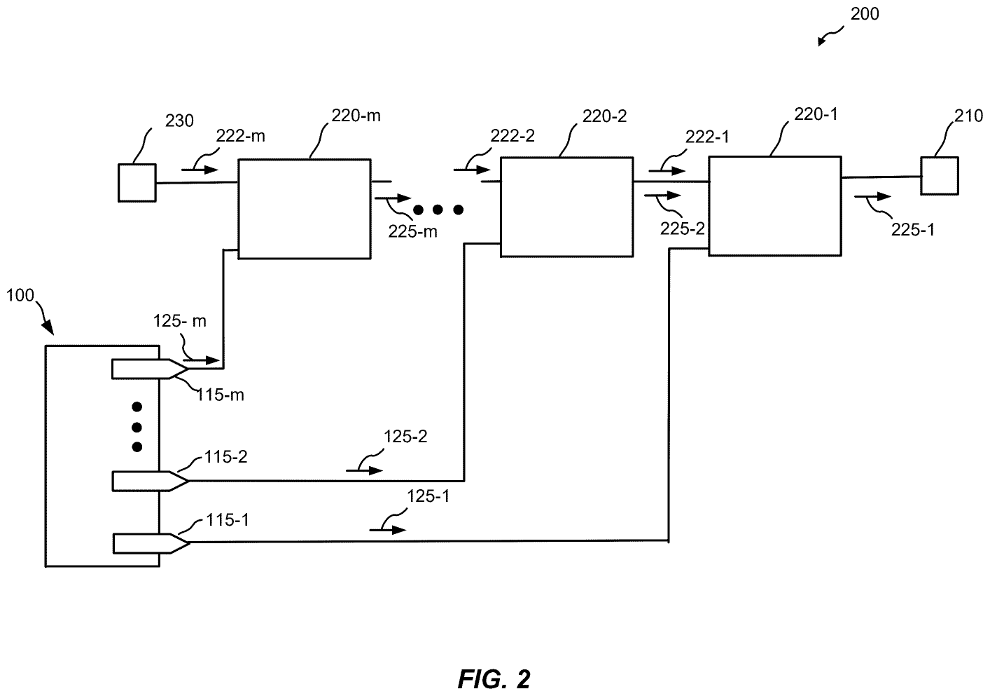

FIG. 2 illustrates a clock staggering scheme for mitigating power surge according to aspects of the present disclosure. In some aspects of the present disclosure and referring to FIGS. 1 and 2, the clock staggering scheme may include using the clock staggering circuit 100 and input signal-staggered output signals scheme 118 to introduce delays in triggering various components of a staggered clock circuit 200. By triggering various components at different times, the clock staggering scheme may reduce surges of power consumptions as described below.

In certain aspects, the staggered clock circuit 200 may include an output terminal 210. The staggered clock circuit 200 may include a plurality of partitions 220-1, 220-2 . . . 220-m where m is a positive integer. Each of the plurality of partitions 220-1, 220-2 . . . 220-m may include one or more portions of the staggered clock circuit 200. In one example, each of the plurality of partitions 220-1, 220-2 . . . 220-m may include one or more of sequential elements, and/or other circuit components. The staggered clock circuit 200 may include an input terminal 230 configured to receive input signals.

During operation of the clock staggering scheme, the clock staggering circuit 100 may output a first output clock signal 125-1 via the first output terminal 115-1. The first output clock signal 125-1 may trigger a first partition 220-1 to receive one or more first input signals 222-1 from a second partition 220-2. Further, the first output clock signal 125-1 may trigger the first partition 220-1 to provide one or more first output signals 225-1 based on the received one or more first input signals. The first partition 220-1 may transmit the one or more first output signals 225-1 to the output terminal 210.

Next, the clock staggering circuit 100 may output a second output clock signal 125-2 via the second output terminal 115-2. The second output clock signal 125-2 may include a delay, d2, with respect to the first output clock signal 125-1 as described above. The second output clock signal 125-2 may trigger a second partition 220-2 to receive one or more second input signals 222-2 from a previous partition (e.g., a third partition). Further, the second output clock signal 125-2 may trigger the second partition 220-2 to provide one or more second output signals 225-2 based on the received one or more second input signals 222-2. Here, the delay in the second output clock signal 125-2 may ensure that the second partition 220-2 outputs the one or more first input signals 222-1 to the first partition 220-1 so that the first partition 220-1 will receive the one or more first input signals 222-1 during a next scan cycle And not during the current scan cycle.

The process above may repeat for each of the plurality of partitions 220-1, 220-2 . . . 220-m. For example, the m^{th} output clock signal 125-m may trigger the m^{th} partition 220-m to receive one or more m^{th} input signals 222-m from the input terminal 230. The m^{th} output clock signal 125-m may trigger the m^{th} partition 220-m to provide one or more m^{th} output signals 225-m based on the received one or more m^{th} input signals.

In some aspects of the present disclosure, each of the plurality of partitions 220-1, 220-2 . . . 220-m may be triggered by a rising edge of the corresponding output clock signal of the plurality of output clock signals 125-1, 125-2 . . . 125-m. In other aspects, each of the plurality of partitions 220-1, 220-2 . . . 220-m may be triggered by a falling edge of the corresponding output clock signal of the plurality of output clock signals 125-1, 125-2 . . . 125-m. Other triggering schemes may also be implemented according to various aspects of the present disclosure.

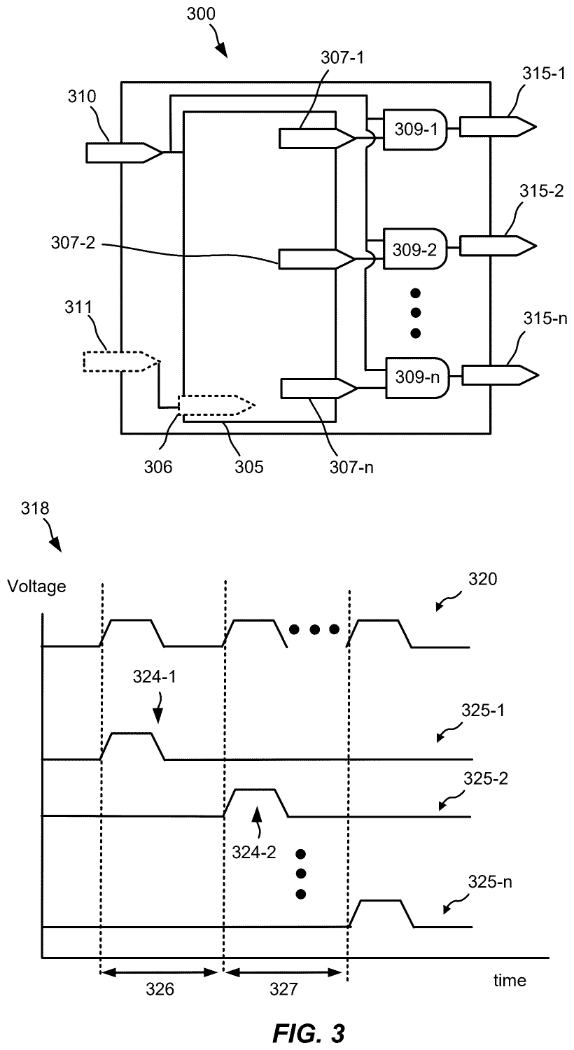

FIG. 3 illustrates an example of a clock sequencing circuit 300 and a graph of an input signal and corresponding sequenced output signals scheme 318, over time, according to aspects of the present disclosure. In some aspects of the present disclosure, the clock sequencing circuit 300 may include an input terminal 310 and a plurality of output terminals 315-1, 315-2 . . . 315-n, where n is a positive integer. The clock sequencing circuit 300 may include a sequencing circuit 305 configured to operate as described below. The clock sequencing circuit 300 may include a plurality of AND gates 309-1, 309-2 . . . 309-n configured to operate as described below. While the example shown in the current figure includes the use of AND gates, other logical gates (e.g., NAND gates) may also be used according to various aspects of the present disclosure. The clock sequencing circuit 300 may include an optional reset input terminal 311 configured to reset the clock sequencing circuit 300 to a known state before any clock pulses is applied.

In some aspects of the present disclosure, the input terminal 310 of the clock sequencing circuit 300 may be configured to receive an input clock signal 320. The sequencing circuit 305 may be configured to receive the input clock signal 320. The sequencing circuit 305 may be configured to sequentially output the a clock enable signal onto one of a plurality of sequencer output terminals 307-1, 307-2 . . . 307-n. For example, the sequencing circuit 305 may output the clock enable signal onto the first sequencer output terminal 307-1 during a first “trigger” of the input clock signal 320 (i.e., the first “pulse” of the input clock signal 320.). The sequencing circuit 305 may output the the clock enable signal onto the second sequencer output terminal 307-2 during a second “trigger” of the input clock signal 320, and so forth and so on. In an optional implementation, the sequencing circuit 305 may include may include an optional reset input terminal 306 configured to receive the reset signal from the optional reset input terminal 311 to reset the sequencing circuit 305 to a known state before any clock pulses is applied.

In certain aspects of the present disclosure, each of the plurality of AND gates 309-1, 309-2 . . . 309-n may receive the input clock signal 320 as a first input, and a signal from a corresponding sequencer output terminal of the plurality of sequencer output terminals 307-1, 307-2 . . . 307-n as a second input. In one instance, an AND gate of the plurality of AND gates 309-1, 309-2 . . . 309-n may receive the input clock signal 320 as the first input, and the clock enable signal as the second input. As such, the corresponding AND gate may output the input clock signal 320. In another instance, another AND gate of the plurality of AND gates 309-1, 309-2 . . . 309-n may receive the input clock signal 320 as the first input, and a null signal as the second input (e.g., no positive voltage). As such, the corresponding AND gate may output a null signal. In other aspects, NAND gates may be used accordingly to an aspect of the present disclosure. For example, an NAND gate (not shown here) may receive an inverse of the input clock signal 320 (NOT input clock signal 320) as the first input and an inverse of the clock enable signal (NOT clock enable signal) as the second input. As such, the NAND gate may output the input clock signal 320. Other aspects of the present disclosure includes using a combination of AND gates and NAND gates, and/or other one or more logic gate structures.

In one aspect of the present disclosure, the plurality of output terminals 315-1, 315-2 . . . 315-n may be configured to output a plurality of output clock signals 325-1, 325-2 . . . 325-n.

During operation, the first output terminal 315-1 may output the resultant value of the first AND gate 309-1. As a result, the first output terminal 315-1 may output the first output clock signal 325-1, which has a pulse 324-1 during a first period 326 of the input clock signal 320. The second output terminal 315-2 may output the second output clock signal 325-2, which has a pulse 324-2 during a second period 327 of the input clock signal 320. Based on the number of n, the clock sequencing circuit 300 may output n output clock signals with filtered pulses as shown in FIG. 3. In other words, the sequencing circuit 305 may sequentially suppress various pulses of the input clock signal 320 that are outputted onto the output terminals 315-1, 315-2 . . . 315-n. As such, the output terminals 315-1, 315-2 . . . 315-n may sequentially output each pulse of the input clock signal 320. Further, the sequencing clock sequencing circuit 300 may periodically output the pulses of the input clock signal 320 across the output terminal 315-1 315-2 . . . 315-n. For example, after n^{th} output terminal 315-n outputs the n^{th} pulse 324-n, the first output terminal 315-1 may, at the next period, output the (n+1)^{th} pulse. Here, the first period 326 and the second period 327 may be a period of the input clock signal. However, aspects of the certain disclosure may include outputting pulses that are not periodic. In other words, the pulses may be separated by one or more time intervals according to certain aspects of the present disclosure.

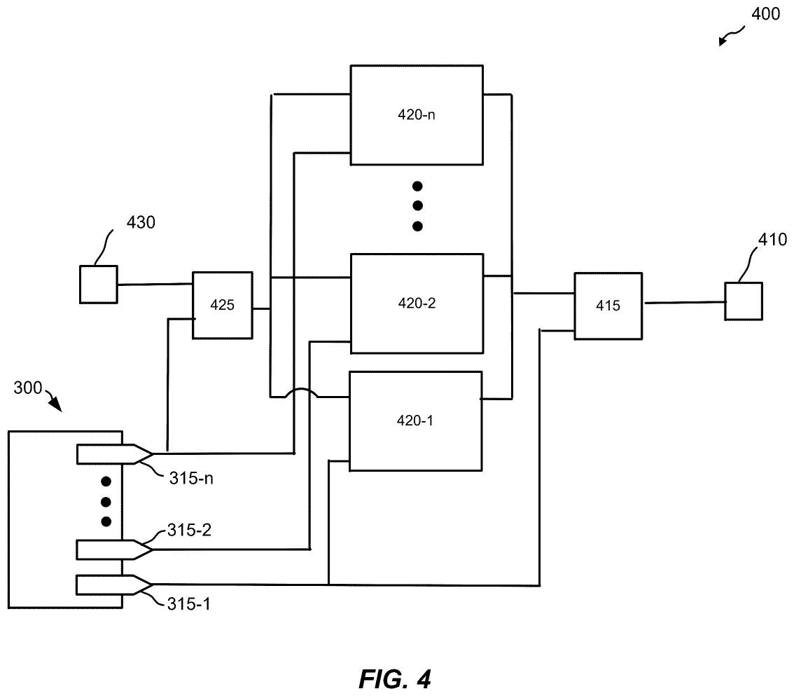

FIG. 4 illustrates an example of a clock sequencing scheme for mitigating power surge according to aspects of the present disclosure. In one aspect, and referring to FIGS. 3 and 4, the clock sequencing scheme may include using the clock sequencing circuit 300 and input signal—sequenced output signals scheme 318 to offset the triggering of various components of a sequenced clock circuit 400. By triggering various components at different times, the clock sequencing scheme may reduce surges of power consumptions as described below.

In certain aspects, the sequenced clock circuit 400 may include an output terminal 410 configured to output signals. The sequenced clock circuit 400 may include an output stage 415. The sequenced clock circuit 400 may include a plurality of partitions 420-1, 420-2 . . . 420-n where n is a positive integer. Each of the plurality of partitions 420-1, 420-2 . . . 420-n may include one or more portions of the sequenced clock circuit 400. In one example, each of the plurality of partitions 420-1, 420-2 . . . 420-n may include one or more of sequential elements, and/or other circuit components. The sequenced clock circuit 400 may include an input stage 425. The sequenced clock circuit 400 may include an input terminal 430 configured to receive input signals.

During operation of the clock sequencing scheme, the clock sequencing circuit 300 may output a first output clock signal 325-1 via the first output terminal 315-1. The first output clock signal 325-1 may trigger the output stage 415 to output any stored data onto the output terminal 410 and/or to receive input signals from any of the partitions 420-1, 420-2 . . . 420-n. Additionally or alternatively, the first output clock signal 325-1 may trigger a first partition 420-1 to receive one or more input signals from the input stage 425. Further, the first output clock signal 325-1 may trigger the first partition 420-1 to provide one or more first output signals based on the received one or more input signals. The first partition 420-1 may transmit the one or more first output signals to the output stage 415.

Next, the clock sequencing circuit 300 may output a second output clock signal 325-2 via the second output terminal 315-2. The second output clock signal 325-2 may include the second pulse 324-2 that is one period away from the first pulse 324-1 of the first output clock signal 325-1 as described above. Other schemes for generating output clock signals may also be possible according to various aspects of the present disclosure.

The second output clock signal 325-2 may trigger a second partition 420-2 to receive one or more input signals from the input stage 425. Further, the second output clock signal 325-2 may trigger the second partition 420-2 to provide one or more second output signals based on the received one or more input signals. Here, the interval between pulses of the second output clock signal 325-2 and the first output clock signal 325-1 may ensure that the second partition 420-2 outputs the one or more input signals to output stage 415 after the output stage has already received its one or more input signals.

The process above may repeat for each of the plurality of partitions 420-1, 420-2 . . . 420-n. For example, the n^{th} output clock signal 325-n may trigger the nth partition 420-n to receive the one or more input signals from the input stage 425. The n^{th} output clock signal 325-n may trigger the n^{th} partition 420-n to provide one or more nth output signals based on the received one or more input signals. Alternatively or additionally, the n^{th} output clock signal 325-n may trigger the input stage 425 to receive the next one or more input signals from the input terminal 430.

In some aspects of the present disclosure, each of the plurality of partitions 420-1, 420-2 . . . 420-n may be triggered by a rising edge of the corresponding output clock signal of the plurality of output clock signals 325-1, 325-2 . . . 325-n. In other aspects, each of the plurality of partitions 420-1, 420-2 . . . 420-n may be triggered by a falling edge of the corresponding output clock signal of the plurality of output clock signals 325-1, 325-2 . . . 325-n. Other triggering schemes may also be implemented according to various aspects of the present disclosure.

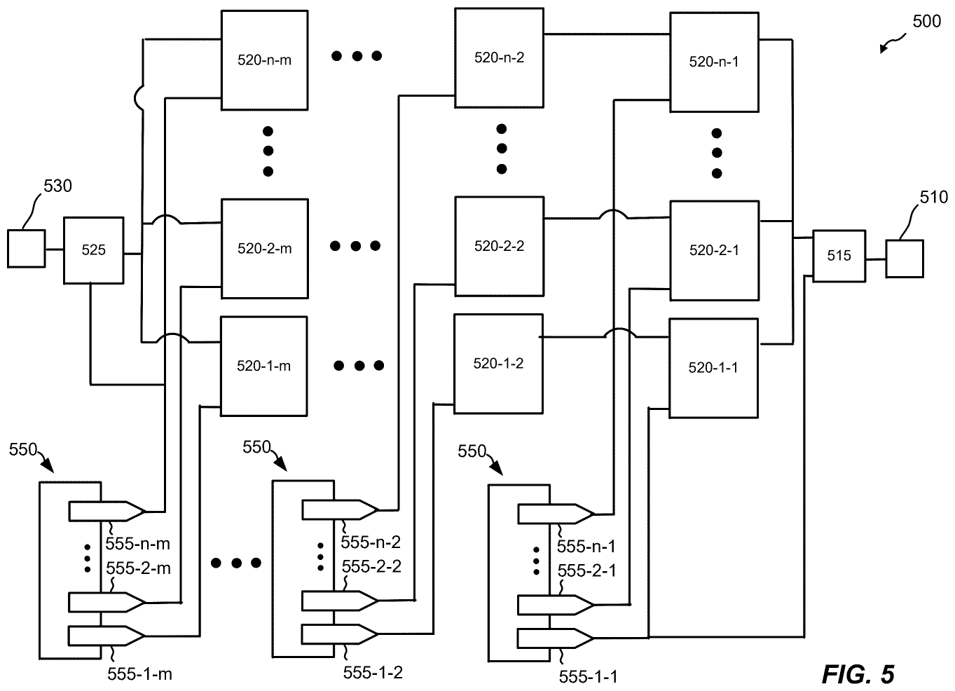

FIG. 5 illustrates an example of a matrix scan scheme according to aspects of the present disclosure. In one aspect, and referring to FIGS. 1-5, the matrix scan scheme may implement both the clock staggering scheme and the clock sequencing scheme as described above with respect to FIGS. 1-4. For example, the matrix scan scheme may include implementing both the clock staggering circuit 100 and the clock sequencing circuit 300 to offset the triggering of various components of a matrix circuit 500. By triggering various components at different times, the matrix scan scheme may reduce surges of power consumptions as described below.

In certain aspects, the matrix circuit 500 may include an output terminal 510 configured to output signals. The matrix circuit 500 may include an output stage 515. The matrix circuit 500 may include n groups of partitions 520-1-M, 520-2-M . . . 520-n-M where n is a positive integer and M is a positive integer between 1 and m as described below. Each group of the n groups of partition may include m partitions 520-N-1, 520-N-2 . . . 520-N-m, where m is a positive integer and N is a positive integer between 1 and n as described above. The integer m may be the same or different than the integer n.

In some aspects, the matrix circuit 500 may include m×n partitions. In other aspects, the matrix circuit 500 may include more or less than m×n partitions. For example, one or more of the n groups of partitions 520-1-M, 520-2-M . . . 520-n-M may include less than or more than m partitions according to various aspects of the present disclosure.

In some aspects of the present disclosure, each of the n groups of partitions 520-1-m, 520-2-m . . . 520-n-m may include one or more portions of the matrix circuit 500. The matrix circuit 500 may include an input stage 525. The matrix circuit 500 may include an input terminal 530 configured to receive input signals.

In certain aspects of the present disclosure, the matrix circuit 500 may include a clock circuit 550. The clock circuit 500 may be configured to receive an input clock signal. Further, the clock circuit 500 may be configured to output a plurality of delayed and/or filtered output clock signals according to various aspects of the present disclosure as described above. For the example, the clock circuit 500 may be configured to output a plurality of delayed or filtered output clock signals using clock staggering or clock sequencing. Here, the clock circuit 550 may be implemented at as a single device or multiple devices according to various aspects of the present disclosure. In some aspects, when outputting output clock signals, the clock circuit 500 may delay, filter, and/or delay and filter the output clock signals as described above. In an aspect, the clock circuit 500 may filter the output clock signal first, followed by delaying the output clock signal with a clock staggering circuit, followed by filtering the output clock signal using a clock sequencing circuit. In other aspects, the clock circuit 500 may filter the output clock signal using a clock sequencing circuit, followed by delaying the output clock signal with a clock staggering circuit.

In one aspect of the present disclosure, the clock circuit 550 may include n groups of output terminals 555-1-M, 555-2-M . . . 555-n-M. Each of the n groups of output terminals may include m output terminals 555-N-1, 555-N-2 . . . 555-N-m.

In some aspects, the clock circuit 550 may receive an input clock signal. The clock circuit 550 may output a first output clock signal, via the output terminal 555-1-1, based on the input clock signal. The clock circuit 550 may output a second output clock signal, via the output terminal 555-1-2, that is delayed (via the method implemented by a clock staggering circuit as described above) compared to the first output clock signal. The clock circuit 550 may output a m^{th} output clock signal, via the output terminal 555-1-m, that is delayed (via the method implemented by a clock staggering circuit as described above) compared to the (m−1)^{th} output clock signal.

In one aspect of the present disclosure, after outputting m output clock signals, the clock circuit 550 may output an m+1 output clock signal, via the output terminal 555-2-1. The m+1 output clock signal may be separated by a time interval (e.g., one or more periods of the input clock signal) compared to the first output clock signal outputted by the output terminal 555-1-1. The process above may be repeated for the remaining output clock signals.

In one aspect of the present disclosure, the m output clock signals generated using the clock staggering circuit may be within a period of the input clock signal. In other aspects, the m output clock signals generated using the clock staggering circuit may be outside a period of the input clock signal. The clock sequencing circuit may be used to generate pulses every one or more periods apart. Other combinations using the clock sequencing circuit and/or the clock staggering circuit may also be used to generate dispersed output clock signals according to various aspects of the present disclosure.

During operation of the matrix scan scheme, the clock circuit 500 may output a first output clock signal via the output terminal 555-1-1. The first output clock signal may trigger the output stage 515 to output any stored data onto the output terminal 510, and/or to receive one or more input signals from one or more of the partitions 520-1-1, 520-2-1 . . . 520-n-1. Additionally or alternatively, the first output clock signal may trigger the partition 520-1-1 to receive one or more first input signals from the partition 520-1-2. Further, the first output clock signal may trigger the partition 520-1-1 to provide one or more first output signals based on the received one or more first input signals. The first partition 520-1-1 may transmit the one or more first output signals to the output stage 515.

Next, the clock circuit 500 may output a second output clock signal via the output terminal 555-1-2. The second output clock signal may be delayed using a clock staggering circuit with respect to the first output clock signal as described above. Other amount of delays may also be possible according to various aspects of the present disclosure.

The second output clock signal may trigger the partition 520-1-2 to receive one or more second input signals from the previous partition. Further, the second output clock signal may trigger the partition 520-1-2 to provide one or more second output signals based on the received one or more first input signals. Here, the delay in the second output clock signal may ensure that the partition 520-1-2 outputs the one or more second output signals to the partition 520-1-1 after the partition 520-1-1 has already received its one or more first input signals.

The process above may repeat for each of the first group of partitions 520-1-1, 520-1-2 . . . 520-1-m. For example, the m^{th} output clock signal may trigger the m^{th} partition 520-1-m to receive the one or more input signals from the input stage 525. The m^{th} output clock signal may trigger the m^{th} partition 520-1-m to provide one or more m^{th} output signals based on the received one or more input signals.

In various aspects of the present disclosure, the clock circuit 550 may output a (m+1)^{th} output clock signal via the output terminal 555-2-1. The (m+1)^{th} output clock signal may be generated based on a clock sequencing circuit. Specifically, the (m+1)^{th} output clock signal may be separated by an interval (e.g., one or more periods of the input clock signal) with respect to the first output clock signal as described above. For example, the (m+1)^{th} output clock signal may be outputted after the first output clock signal by one or more periods of the input clock signal. Other amount of clock signal dispersion scheme may also be possible according to various aspects of the present disclosure.

The (m+1)^{th} output clock signal may trigger the partition 520-2-1 to receive one or more (m+1)^{th} input signals from the previous partition. Further, the (m+1)^{th} output clock signal may trigger the partition 520-1-2 to provide one or more (m+1)^{th} output signals based on the received one or more (m+1)^{th} input signals.

The process above may repeat for each of the second group of partitions 520-2-1, 520-2-2 . . . 520-2-m. For example, the 2m^{th} output clock signal may trigger the 2m^{th} partition 520-2-m to receive the one or more input signals from the input stage 525. The 2m^{th} output clock signal may trigger the 2m^{th} partition 520-2-m to provide one or more 2m^{th} output signals based on the received one or more input signals.

In one aspect of the present disclosure, the process above may repeat for each group of partitions. For example, the nm^{th} output terminal 555-n-m may output the nm^{th} output clock signal to trigger the nm^{th} partition 520-n-m to receive the one or more input signals from the input stage 525. The nm^{th} output clock signal may trigger the nm^{th} partition 520-n-m to provide one or more nm^{th} output signals based on the received one or more input signals from the input stage 525. Further, the nm^{th} output clock signal may trigger the input stage 525 to receive one or more next input signals from the input terminal 530.

In some aspects of the present disclosure, each of the plurality of partitions 520-1-1, 520-1-2 . . . 520-1-m . . . 520-n-m may be triggered by a rising edge of the corresponding output clock signal of the plurality of output clock signals transmitted by the clock circuit 550. In other aspects, each of the plurality of partitions 520-1-1, 520-1-2 . . . 520-1-m . . . 520-n-m may be triggered by a falling edge of the corresponding output clock signal of the plurality of output clock signals transmitted by the clock circuit 550. Other triggering schemes may also be implemented according to various aspects of the present disclosure.

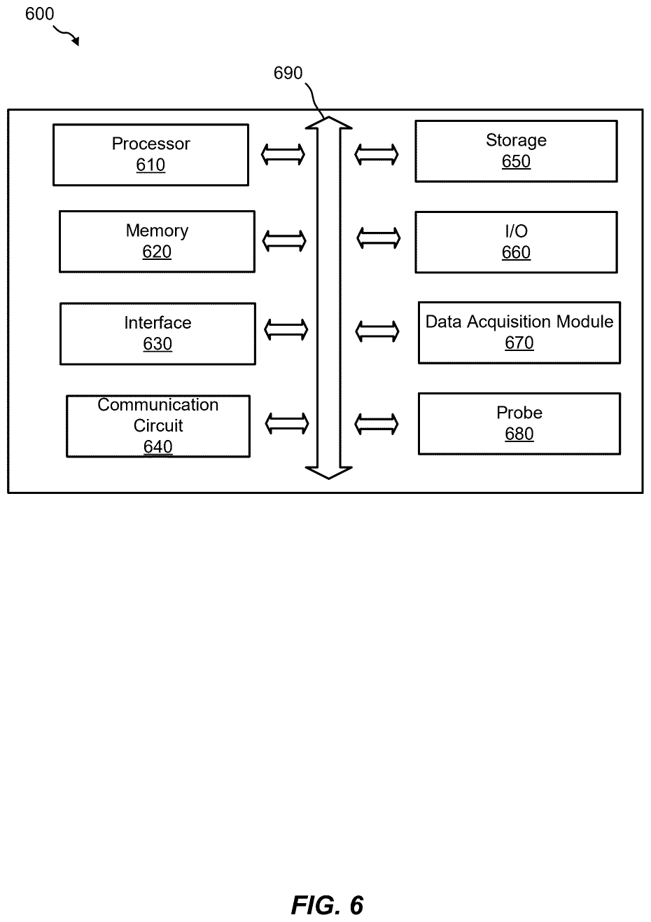

FIG. 6 illustrates an example of a measurement system 600 for measuring current and/or voltage output from a circuit, such as the staggered clock circuit 200, the sequenced clock circuit 400, and/or the matrix circuit 500 (FIGS. 2, 4, and 5). The measurement system 600 may be in a single package or as a chip set assembly with multiple components. The measurement system 600 may include a processor 610 configured to execute instructions stored in a memory 620. The memory 620 may include computer executable instructions. The measurement system 600 may include an interface circuit 630 configured to provide a hardware interface with external devices. The measurement system 600 may include a communication circuit 640 configured to communicate via wired or wireless communication channels. The measurement system 600 may include a storage 650 configured to store digital information. The measurement system 600 may include an input/output (I/O) interface device 660 configured to receive input signals and/or transmit output signals.

In some aspects of the present disclosure, the measurement system 600 may include a data acquisition module 670 configured to analyze, compute, arrange, and/or display voltage and/or current data measured by the measurement system 600. The measurement system 600 may include one or more probes 680 configured to contact the input terminals and/or the output terminals, such as the input terminals 230, 430, 530 and/or the output terminals 210, 410, 510 of FIGS. 2, 4, and 5. Specifically, the one or more probes 680 may be configured to contact the input terminals and/or the output terminals to test the operations of various circuits, such as the staggered clock circuit 200, the sequenced clock circuit 400, and/or the matrix circuit 500 (FIGS. 2, 4, and 5).

In certain aspects, the measurement system 600 may include a bus 690 configured to interconnect the components of the measurement system 600.

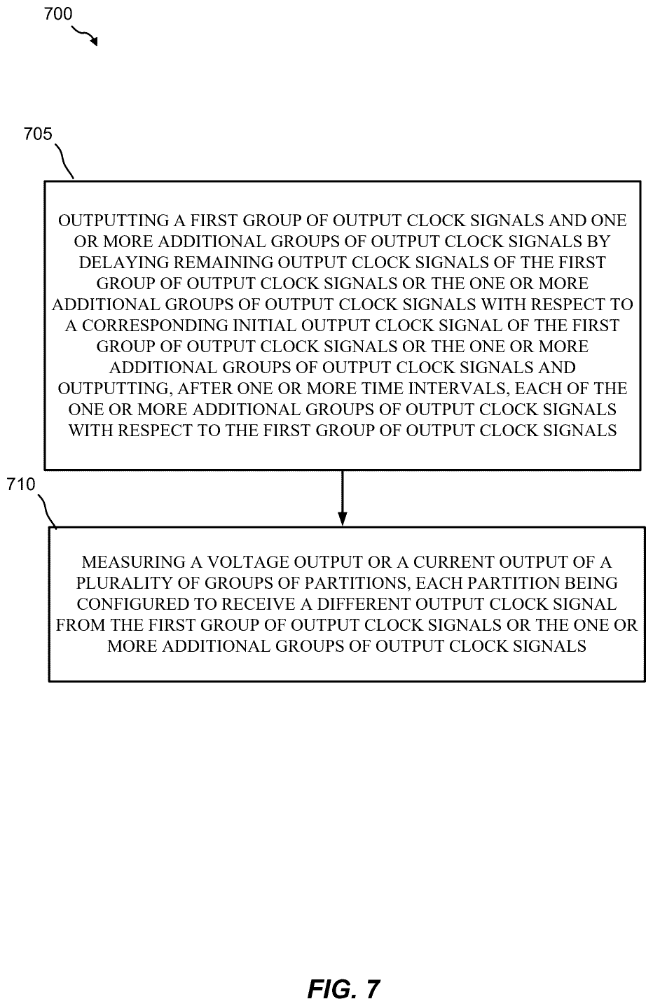

FIG. 7 illustrates a method 700 of performing a matrix scan according to various aspects of the present disclosure. The method 700 may be performed by one or more of the clock staggering circuit 100, the clock sequencing circuit 300, the matrix circuit 500, the clock circuit 550, the measurement system 600, and/or one or more subcomponents of the clock staggering circuit 100, the clock sequencing circuit 300, the matrix circuit 500, the clock circuit 550, and/or the measurement system 600.

At 705, the method 700 may output a first group of output clock signals and one or more additional groups of output clock signals by delaying remaining output clock signals of the first group of output clock signals or the one or more additional groups of output clock signals with respect to a corresponding initial output clock signal of the first group of output clock signals or the one or more additional groups of output clock signals and outputting, after one or more time intervals, each of the one or more additional groups of output clock signals with respect to the first group of output clock signals. The clock staggering circuit 100, the clock sequencing circuit 300, the matrix circuit 500, and/or the clock circuit 550 may be configured to, and/or provide means for, outputting a first group of output clock signals and one or more additional groups of output clock signals by delaying remaining output clock signals of the first group of output clock signals or the one or more additional groups of output clock signals with respect to a corresponding initial output clock signal of the first group of output clock signals or the one or more additional groups of output clock signals and outputting, after one or more time intervals, each of the one or more additional groups of output clock signals with respect to the first group of output clock signals.

At 710, the method 700 may measure a voltage output or a current output of a plurality of groups of partitions, each partition being configured to receive a different output clock signal from the first group of output clock signals or the one or more additional groups of output clock signals. The measurement system 600 may be configured to, and/or provide means for measuring a voltage output or a current output of a plurality of groups of partitions, each partition being configured to receive a different output clock signal from the first group of output clock signals or the one or more additional groups of output clock signals.

Aspects of the present disclosure include a matrix circuit having a clock circuit configured to output a first group of output clock signals and one or more additional groups of output clock signals, the clock circuit comprising: at least one clock staggering circuit configured to delay remaining output clock signals of the first group of output clock signals or the one or more additional groups of output clock signals with respect to a corresponding initial output clock signal of the first group of output clock signals or the one or more additional groups of output clock signals, and at least one clock sequencing circuit configured to output, after one or more time intervals, each of the one or more additional groups of output clock signals with respect to the first group of output clock signals, and a plurality of groups of partitions, each partition being configured to receive a different output clock signal from the first group of output clock signals or the one or more additional groups of output clock signals.

Aspects of the present disclosure include the matrix circuit above, wherein each partition of the plurality of groups of partitions is configured to perform one or more of, in response to receiving the different output clock signal, receiving a corresponding input signal or providing a corresponding output signal.

Aspects of the present disclosure include any of the matrix circuits above, wherein each partition of the plurality of groups of partitions is further configured to provide the corresponding output signal based on the corresponding input signal.

Aspects of the present disclosure include any of the matrix circuits above, wherein each clock staggering circuit of the at least one clock staggering circuit includes a plurality of groups of delay lines configured to delay the remaining output clock signals.

Aspects of the present disclosure include any of the matrix circuits above, wherein the clock circuit is configured to receive an input clock signal having a period.

Aspects of the present disclosure include any of the matrix circuits above, wherein the at least one clock sequencing circuit is configured to output each of the one or more additional groups of output clock signals that are one or more periods of the input clock signal after the first group of output clock signals.

Aspects of the present disclosure include any of the matrix circuits above, further comprises an output stage, wherein the clock circuit is configured to transmit the initial output clock signal of the first group of output clock signals to the output stage to trigger the output stage to transmit an output signal to an output terminal.

Aspects of the present disclosure include any of the matrix circuits above, further comprises an input stage, wherein the clock circuit is configured to transmit a last signal of the one or more additional groups of output clock signals to the input stage to trigger the input stage to receive an input signal from an input terminal.

Aspects of the present disclosure include any of the matrix circuits above, wherein each partition of the plurality of groups of partitions comprises one or more sequential elements.

Aspects of the present disclosure include any of the matrix circuits above, wherein the clock circuit is further configured to output each of the first group of output clock signals and the one or more additional groups of output clock signals to a corresponding partition of the plurality of groups of partitions.

Aspects of the present disclosure include any of the matrix circuits above, further comprises a measurement system configured to measure a voltage output or a current output of a plurality of groups of partitions, each partition being configured to receive a different output clock signal from the first group of output clock signals or the one or more additional groups of output clock signals.

The above detailed description set forth above in connection with the appended drawings describes examples and does not represent the only examples that may be implemented or that are within the scope of the claims. The term “example,” when used in this description, means “serving as an example, instance, or illustration,” and not “preferred” or “advantageous over other examples.” The detailed description includes specific details for the purpose of providing an understanding of the described techniques. These techniques, however, may be practiced without these specific details. For example, changes may be made in the function and arrangement of elements discussed without departing from the scope of the disclosure. Also, various examples may omit, substitute, or add various procedures or components as appropriate. For instance, the methods described may be performed in an order different from that described, and various steps may be added, omitted, or combined. Also, features described with respect to some examples may be combined in other examples. In some instances, well-known structures and apparatuses are shown in block diagram form in order to avoid obscuring the concepts of the described examples.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, computer-executable code or instructions stored on a computer-readable medium, or any combination thereof.

Several aspects of telecommunication systems will now be presented with reference to various apparatus and methods. These apparatus and methods will be described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an clement, or any portion of an element, or any combination of elements may be implemented as a “processing system” that includes one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more example embodiments, the functions described may be implemented in hardware, software, or any combination thereof. If implemented in software, the functions may be stored on or encoded as one or more instructions or code on a computer-readable medium.

The various illustrative blocks and components described in connection with the disclosure herein may be implemented or performed with a specially-programmed device, such as but not limited to a processor, a digital signal processor (DSP), an ASIC, a FPGA or other programmable logic device, a discrete gate or transistor logic, a discrete hardware component, or any combination thereof designed to perform the functions described herein. A specially-programmed processor may be a microprocessor, but in the alternative, the processor may be any conventional processor, controller, microcontroller, or state machine. A specially-programmed processor may also be implemented as a combination of computing devices, e.g., a combination of a DSP and a microprocessor, multiple microprocessors, one or more microprocessors in conjunction with a DSP core, or any other such configuration.

The functions described herein may be implemented in hardware, software executed by a processor, firmware, or any combination thereof. If implemented in software executed by a processor, the functions may be stored on or transmitted over as one or more instructions or code on a non-transitory computer-readable medium. Other examples and implementations are within the scope and spirit of the disclosure and appended claims. For example, due to the nature of software, functions described above may be implemented using software executed by a specially programmed processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items prefaced by “at least one of” indicates a disjunctive list such that, for example, a list of “at least one of A, B, or C” means A or B or C or AB or AC or BC or ABC (i.e., A and B and C).

Computer-readable media includes both computer storage media and communication media including any medium that facilitates transfer of a computer program from one place to another. A storage medium may be any available medium that may be accessed by a general purpose or special purpose computer. By way of example, and not limitation, computer-readable media may comprise RAM, ROM, EEPROM, CD-ROM or other optical disk storage, magnetic disk storage or other magnetic storage devices, or any other medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The previous description of the disclosure is provided to enable a person skilled in the art to make or use the disclosure. Various modifications to the disclosure will be readily apparent to those skilled in the art, and the common principles defined herein may be applied to other variations without departing from the spirit or scope of the disclosure. Furthermore, although elements of the described aspects may be described or claimed in the singular, the plural is contemplated unless limitation to the singular is explicitly stated. Additionally, all or a portion of any aspect may be utilized with all or a portion of any other aspect, unless stated otherwise. Thus, the disclosure is not to be limited to the examples and designs described herein but is to be accorded the widest scope consistent with the principles and novel features disclosed herein.

What is claimed is:

1. A matrix circuit, comprising:
a clock circuit configured to output a first group of output clock signals and one or more additional groups of output clock signals, the clock circuit comprising at least one of:
at least one clock staggering circuit configured to delay remaining output clock signals of the first group of output clock signals or the one or more additional groups of output clock signals with respect to a corresponding initial output clock signal of the first group of output clock signals or the one or more additional groups of output clock signals, and
at least one clock sequencing circuit configured to output, after one or more time intervals, each of the one or more additional groups of output clock signals with respect to the first group of output clock signals; and
a plurality of groups of partitions, each partition being configured to receive a different output clock signal from the first group of output clock signals or the one or more additional groups of output clock signals.

2. The matrix circuit of claim 1, wherein each partition of the plurality of groups of partitions is configured to perform one or more of, in response to receiving the different output clock signal, receiving a corresponding input signal or providing a corresponding output signal.

3. The matrix circuit of claim 2, wherein each partition of the plurality of groups of partitions is further configured to provide the corresponding output signal based on the corresponding input signal.

4. The matrix circuit of claim 1, wherein each clock staggering circuit of the at least one clock staggering circuit includes a plurality of groups of delay lines configured to delay the remaining output clock signals.

5. The matrix circuit of claim 1, wherein the clock circuit is configured to receive an input clock signal having a period.

6. The matrix circuit of claim 5, wherein the at least one clock sequencing circuit is configured to output each of the one or more additional groups of output clock signals that are one or more periods of the input clock signal after the first group of output clock signals.

7. The matrix circuit of claim 1, further comprises an output stage, wherein the clock circuit is configured to transmit an initial output clock signal of the first group of output clock signals to the output stage to trigger the output stage to transmit an output signal to an output terminal.

8. The matrix circuit of claim 1, further comprises an input stage, wherein the clock circuit is configured to transmit a last signal of the one or more additional groups of output clock signals to the input stage to trigger the input stage to receive an input signal from an input terminal.

9. The matrix circuit of claim 1, wherein each partition of the plurality of groups of partitions comprises one or more sequential elements.

10. The matrix circuit of claim 1, wherein the clock circuit is further configured to output each of the first group of output clock signals and the one or more additional groups of output clock signals to a corresponding partition of the plurality of groups of partitions.

11. A system, comprising:
a clock circuit configured to output a first group of output clock signals and one or more additional groups of output clock signals, the clock circuit comprising at least one of:
at least one clock staggering circuit configured to delay remaining output clock signals of the first group of output clock signals or the one or more additional groups of output clock signals with respect to a corresponding initial output clock signal of the first group of output clock signals or the one or more additional groups of output clock signals, and
at least one clock sequencing circuit configured to output, after one or more time intervals, each of the one or more additional groups of output clock signals with respect to the first group of output clock signals; and
a measurement system configured to measure a voltage output or a current output of a plurality of groups of partitions, each partition being configured to receive a different output clock signal from the first group of output clock signals or the one or more additional groups of output clock signals.

12. The system of claim 11, wherein each partition of the plurality of groups of partitions is configured to perform one or more of, in response to receiving the different output clock signal, receiving a corresponding input signal or providing a corresponding output signal.

13. The system of claim 12, wherein each partition of the plurality of groups of partitions is further configured to provide the corresponding output signal based on the corresponding input signal.

14. The system of claim 11, wherein each clock staggering circuit of the at least one clock staggering circuit includes a plurality of groups of delay lines configured to delay the remaining output clock signals.

15. The system of claim 11, wherein the clock circuit is configured to receive an input clock signal having a period.

16. The system of claim 15, wherein the at least one clock sequencing circuit is configured to output each of the one or more additional groups of output clock signals that are one or more periods of the input clock signal after the first group of output clock signals.

17. The system of claim 11, wherein the clock circuit is configured to transmit an initial output clock signal of the first group of output clock signals to an output stage associated with the plurality of groups of partitions to trigger the output stage to transmit an output signal to an output terminal.

18. The system of claim 11, wherein the clock circuit is configured to transmit a last signal of the one or more additional groups of output clock signals to an input stage associated with the plurality of group of partitions to trigger the input stage to receive an input signal from an input terminal.

19. The system of claim 11, wherein each partition of the plurality of groups of partitions comprises one or more sequential elements.

20. The system of claim 11, wherein the clock circuit is further configured to output each of the first group of output clock signals and the one or more additional groups of output clock signals to a corresponding partition of the plurality of groups of partitions.
